(19) United States
(12) Patent Application Publication
(10) Pub. No.: US 2017/0352582 A1
(43) Pub. Date: Dec. 7, 2017

(54) PROCESS OF FORMING AN ELECTRONIC DEVICE INCLUDING A BOND PAD

(71) Applicant: SEMICONDUCTOR COMPONENTS INDUSTRIES, LLC, Phoenix, AZ (US)

(72) Inventor: Eiji KUROSE, Ora-Gun (JP)

(73) Assignee: SEMICONDUCTOR COMPONENTS INDUSTRIES, LLC, Phoenix, AZ (US)

(21) Appl. No.: 15/175,191

(22) Filed: Jun. 7, 2016

(51) Int. Cl. H01L 21/768; H01L 21/48

(52) U.S. Cl. CPC H01L 21/7682; H01L 21/76877; H01L 21/76831; H01L 21/4853; H01L 21/486; H01L 21/76802

(57) ABSTRACT

A process of forming an electronic device including providing a substrate having a first surface and a second surface opposite the first surface; etching the substrate along the first surface to define a trench; forming a via within the trench; applying a tape including an adhesive to the first surface, wherein the adhesive of the tape is spaced apart from the first surface by a distance; and operating on the second surface of the substrate.

### FIELD OF THE DISCLOSURE

The present disclosure relates to electronic devices and processes of forming electronic devices, and more particularly to electronic devices including trenches and processes of forming the same.

### RELATED ART

Through-wafer vias are typically used to form connections between different die in a stacked configuration. Such vias can be formed by forming circuitry at one of the major surfaces of a wafer. The wafer is then thinned by backgrinding or other mechanical operation, and then vias are formed through all or substantially all of the remaining thickness of the wafer. Each via has a width that is similar to but slightly smaller than the area occupied by a bond pad. The vias consist of bulk silicon, polysilicon, an elemental metal, a metal alloy, a conductive metal nitride, or a combination thereof and do not include a discrete internal feature. In other words, the vias are simple miniature wires.

Traditional processes of fabricating through-wafer vias can cause surface deformations along the die. Cracks, residue, and material left on the die can cause wire bonding attachment complications and device issues, or failure. Industries continue to demand improved electronic devices which do not include deformations caused by traditional processes of through-wafer via formation.

### BRIEF DESCRIPTION OF THE DRAWINGS

Embodiments are illustrated by way of example and are not limited in the accompanying figures.

FIG. 1 includes a cross-sectional view of an electronic device including a substrate defining a trench extending from a first surface.

FIG. 2 includes a cross-sectional view of the electronic device of FIG. 1 after forming a via within the trench.

FIG. 3 includes a cross-sectional view of the electronic device of FIG. 2 after forming a bond pad and a coating over the substrate and via.

FIG. 4 includes a cross-sectional view of the electronic device of FIG. 3 as seen along Line A-A in FIG. 3

FIG. 5 includes a cross-sectional view of the electronic device of FIG. 3 after applying tape over the coating.

FIG. 6 includes a cross-sectional view of the electronic device of FIG. 4 after inverting the device and operating on the second surface thereof.

FIG. 7 includes a cross-sectional view of the electronic device of FIG. 5 after further operating on the second surface to form a conductive layer, a mask layer, and a conductive bump.

FIG. 8 includes a cross-sectional view of the electronic device of FIG. 6 during removal of the tape.

FIG. 9 includes a cross-sectional view of another electronic device including an air cavity between a substrate and tape applied over a surface of the substrate.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings can certainly be utilized in this application. While numerical ranges are described herein to provide a better understanding of particular embodiments, after reading this specification, skilled artisans will appreciate that values outside the numerical ranges may be used without departing from the scope of the present invention.

An electronic device may or may not include an electronic component. For example, an interposer may be at least a part of an electronic device that may not include any electronic components. The interposer may electrically connect an electronic component on a substrate or workpiece with another electronic component or terminal on a different substrate or workpiece.

The term “metal” or any of its variants when referring to a material is intended to mean to a material, whether or not a molecular compound, that includes an element that is within any of the Groups 1 to 12, within Groups 13 to 16, an element that is along and below a line defined by atomic numbers 13 (Al), 31 (Ga), 50 (Sn), 51 (Sb), and 84 (Po). Metal does not include Si or Ge, by itself. Group numbers corresponding to columns within the Periodic Table of the elements use the “New Notation” convention as seen in the CRC Handbook of Chemistry and Physics, 81^{st} Edition (2000-2001).

The term “substantially fills” when referring to a material being formed within an opening or a trench, is intended to mean that most of the opening or trench, or most of a remainder of the opening or trench (if a liner, barrier, or other relatively-thin layer has been previously formed) is filled by the material. Note that an incidental void may be formed when substantially filling the opening or trench with the material. The term “substantially completely fills” is intended to mean that substantially all of the opening or trench or substantially all of the remainder of the opening or trench is filled with the material without a significant number of voids formed within the opening or trench.

The terms “comprises,” “comprising,” “includes,” “including,” “has,” “having,” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read such that the plurals include one or at least one and the singular also includes the plural, unless it is clear that it is meant otherwise. For example, when a single item is described herein, more than one item may be used in place of a single item. Similarly, where more than one item is described herein, a single item may be substituted for that more than one item.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the semiconductor and electronic arts.

A process of forming an electronic device can include etching a substrate along a first surface to define a trench and then forming a via within the trench. Tape can then be applied over the first surface of the substrate such that adhesive of the tape is spaced apart from the first surface by a distance, such as an air gap. In an embodiment, a coating can be disposed between the adhesive of the tape and the first surface. The coating can include a polymer, such as a polyimide or a resin, such as a phenol resin. In an embodiment, the coating is applied over the first surface using a spin coating process. The final coating can have a thickness in a range of 1 μm and 20 μm.

A second surface of the substrate, opposite the first surface, can then be operated on, for example, by removing a portion of the substrate using an isotropic etch along the second surface and forming a first conductive structure along the second surface. The conductive structure can be electrically connected to the via.

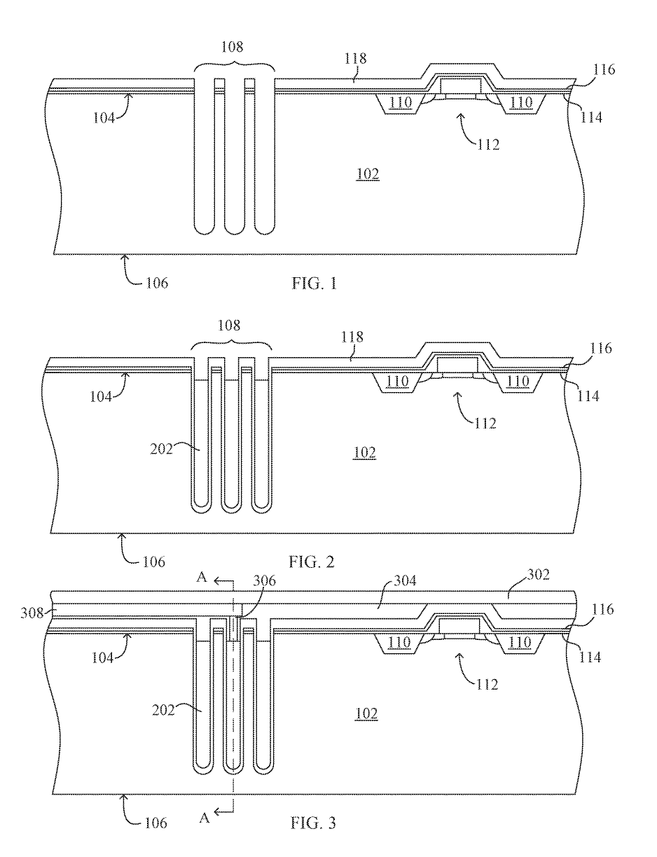

FIG. 1 includes a cross-sectional view of a workpiece including a portion of a substrate 102 having first and second surfaces 104 and 106 spaced apart by a thickness of the substrate 102. The substrate 102 can include a monocrystalline semiconductor wafer, a semiconductor-on-insulator wafer, a flat panel display (e.g., a silicon layer over a glass plate), or another substrate conventionally used to form electronic devices. The portion of the substrate 102 as illustrated in FIG. 1 can include a Group 14 element (e.g., carbon, silicon, germanium, or any combination thereof) that includes an n-type or p-type dopant. In another embodiment, the substrate 102 includes a III-V or II-VI semiconductor material.

The substrate 102 can include field isolation regions, active components, or other electronic components formed within or over the first surface 104. Field isolation regions 110 and a transistor 112 can be formed at least partly within the substrate 102. Other or different active or other electronic components can be are formed within or over the first surface 104. In a particular embodiment, no electronic components are formed along the first and second surfaces 104 and 106 because a subsequent backgrind or other operation will be performed to significantly reduce the thickness of the substrate 102. When the substrate 102 is in the form of a wafer, the initial thickness substantially corresponds to the thickness of the wafer before any processing is performed. In an embodiment, the thickness may be no greater than approximately 2000 microns, and in another embodiment, the thickness may be no greater than approximately 900 microns. In a further embodiment, the thickness is at least approximately 110 microns, and in another further embodiment, the thickness is at least approximately 150 microns. In a particular embodiment, the thickness is in a range of approximately 600 microns to approximately 800 microns. In another particular embodiment, the substrate 102 has a thickness in a range of approximately 150 microns to approximately 120 microns. In an embodiment, the substrate 102 may have a nominal size (for example, a nominal diameter) of at least 150 mm. Although the substrate 102 does not have a theoretical upper limit, the nominal size of the substrate 102 may not exceed 400 mm.

A pad layer 114, a stopping layer 116 (e.g., a polish-stop layer or an etch-stop layer), and a mask layer 118 can be formed over the substrate 102 using, for example, a thermal growth technique, a deposition technique, or a combination thereof. Each of the pad layer 114 and the stopping layer 116 can include an oxide, a nitride, an oxynitride, another suitable material, or any combination thereof. In an embodiment, the stopping layer 116 has a different composition as compared to the pad layer 114. In a particular embodiment, the pad layer 114 includes an oxide, and the stopping layer 116 includes a nitride. The mask layer 118 can be formed over the stopping layer 116 and is patterned to define openings (not illustrated) under which trenches 108 in the substrate 102 will be formed. In an embodiment, the mask layer 118 includes an organic resist material, and in another embodiment, the mask layer 118 may include an inorganic material different from the substrate 102.

An etch operation is performed to pattern the pad layer 114, stopping layer 116, and substrate 102 to define trenches, including the trench 108, that extend from the first surface 104 towards but does not reach the second surface 106. The trench 108 can have a depth as measured from the first surface 104. The depth can be at least 40 microns. In an embodiment, the depth can be at least 75 microns, and in another embodiment, can be at least 110 microns, at least 200 microns, or more. The widths of the trench 108 may depend in part on the depth of the trench 108. In an embodiment, the width of the trench 108 can be in a range of 0.2 microns to 2 microns, and in a particular embodiment, can be in a range of 0.5 microns to 0.9 microns. Each of the portions of the trench 108 as illustrated in FIG. 1 can be in a range of approximately 0.5 microns to approximately 5 microns, and in a particular embodiment can be in a range of approximately 2.0 microns to 4.0 microns.

The shapes of the trench 108 can be a little narrower near the bottom of the trench 108 as compared to a location closer to the first surface 104. Thus, the widths of the trench 108 may be tapered. The bottoms of the trench 108 can be generally flat; however, the corners between the sidewalls and bottom of each trench may be rounded. The etch can be performed by any number of deep silicon etch tools using an etch process, such as a process as described in U.S. Pat. No. 7,285,228, which is incorporated herein by reference in its entirety. The process disclosed in the patent is a well-known process for high aspect ratio deep silicon etching that cycles between isotropic surface passivation of the trench walls, reactive ion etch passivation clearing at the trench bottom, and isotropic silicon etching of the trench bottom opening. In an embodiment, the selectivity of silicon to an organic resist material can be in a range of approximately 80:1 to 100:1. If a mask uses a metal that is not significantly etched by fluorine, such as an AlN mask, the selectivity can be substantially higher. Vertical or tapered or shaped trenches can be controlled by the etching conditions. After forming the trenches, the optional mask layer is removed.

FIG. 2 includes an illustration of a cross-sectional view of the portion of the substrate 102 after substantially filling the trench 108 with a fill material and partially recessing the fill material to form the via 202.

The insulating layer can be formed to insulate the sidewalls and bottoms of the trenches before forming the fill material. In an embodiment, the insulating layer has a thickness no greater than 900 nm, and in another embodiment, has a thickness no greater than 700 nm. In a further embodiment, the insulating layer has a thickness of at least 11 nm, and in still a further embodiment, the insulating layer has a thickness of at least 100 nm. In a further embodiment, the insulating layer may not be present. The insulating layer can include a single film or a plurality of films, wherein each film can include an oxide, a nitride, or an oxynitride and can be formed thermally or by a deposition. In a particular embodiment, a thermal oxidation is performed to form at least part of the insulating layer. When the stopping layer includes a nitride, the stopping layer can act as an oxidation barrier to reduce the oxidation of the substrate along the first surface 104.

The fill material for the via 202 can include a single material or a plurality of materials that can be in the form of a layer, a plurality of layers, a single film, or a plurality of films. The fill material can be conductive, resistive, an insulator, or a combination thereof (for example, when forming capacitors within the trenches). The actual material, both composition(s) and number of material(s) will depend on the electronic component being formed. The fill material can be a conductive material and include amorphous silicon, polycrystalline silicon, a metal (an elemental metal, as opposed to a molecular compound), an alloy, a metal nitride, a metal-semiconductor compound, a metal-semiconductor-nitrogen compound, or the like. The composition of the conductive material may depend on when the conductive material is formed. The via 202 may be formed before or after forming electronic components at least partly within the substrate 102. Such electronic components can include an active component (for example, a transistor), a passive component (for example, a resistor, a capacitor, a diode, or the like), or any combination thereof are at least partly formed within the substrate 102. If the conductive material is formed before forming such electronic component within the substrate 102, the conductive material may have to withstand relatively high temperatures, such as greater than 800° C. An exemplary material can include silicon or a refractory metal element. If the conductive material is formed after forming such electronic component within the substrate 102, the conductive material may not need to withstand a temperature greater than 800° C. In a particular embodiment, the conductive material is formed just before or as part of the interlevel dielectric (ILD)/interconnect sequence, and the conductive material may be exposed to temperatures as high as 500° C. An exemplary material can include silicon or a refractory metal element, copper, silver, a noble metal element, or any combination thereof.

The fill material may include an adhesion film, a barrier film, and a conductive-fill film. In a particular embodiment, the adhesion film includes a refractory metal, the barrier layer includes a refractory metal nitride, and the conductive-fill film includes a refractory metal different from the adhesion film. In another particular embodiment, the fill material includes doped polysilicon.

The fill material can be formed by depositing the fill material using a chemical vapor deposition, physical vapor deposition, plating, coating, another suitable technique, or any combination thereof. In a particular embodiment, the fill material is deposited conformally. The thickness of the fill material is sufficient to substantially fill the trenches, including the trench 108, and in a particular embodiment, the fill material substantially completely fills the trenches. The actual thickness may depend on the width of the trenches. As the trenches are wider, a thicker deposition of the fill material may be needed. In an embodiment, the thickness will be at least half of the width, and can be thicker to account for nonuniformity of the widths of the trenches, thickness of the fill material across the substrate 102, or both. In a particular embodiment, the thickness of the fill material may be approximately 0.9 microns when the widths of the trenches are approximately 1.6 microns. In another particular embodiment, the thickness of the fill material may be approximately 1.5 microns when the widths of the trenches are approximately 2.8 microns. After reading this specification, skilled artisans will appreciate that making the fill material too thick is safer than making the fill material too thin. However, as the thickness increases, longer deposition times, higher costs for the fill material, and longer and more costly subsequent removal operations will result. Accordingly, in an embodiment, the thickness of the fill material is no thicker than approximately three times the width of the widest trench, and in another embodiment, the thickness of the fill material is no thicker than approximately twice the width of the widest trench. As deposited, the fill material will overlie the pad layer and the stopping layer (not illustrated).

A removal operation can be performed to remove a portion of the fill material that overlies the stopping layer. The removal operation can be performed using an etching or polishing technique or using a patterned etch process to leave a conductive routing layer over the stopping layer (not illustrated). The tops of the remaining portions of the fill material may be recessed below the exposed surface of the stopping layer. In a particular embodiment, the fill material is recessed to an elevation at or near the elevation of the first surface 104.

Processing continues until the processing along the first surface 104 of the substrate 102 is substantially completed. An insulating layer 304 is formed over the substrate 102 in FIGS. 3 and 4. The insulating layer 304 can include one or more films of an oxide, a nitride, an oxynitride, or any combinations thereof. A thickness of the insulating layer 304 can be in a range of approximately 0.5 microns to approximately 3 microns. Portions of the insulating layer 304 are removed to define contact openings in which conductive plug 306 is formed. The conductive plug 306 makes electrical connection to a bond pad 308. The conductive plug 306 also makes electrical connection to the via 202. Additional insulating and interconnect levels (not illustrated in FIGS. 3 and 4) can be formed if needed or desired.

A coating 302 can be formed over the first surface 104 of the substrate 102. In an embodiment, the coating 302 includes a photosensitive resist resin. In a particular embodiment, the coating 302 includes a poly phenol resin. In another embodiment, the coating 302 includes a polyimide. The coating 302 has a thickness in a range of 1 μm and 20 μm, such as in a range of 1 μm and 15 μm, in a range of 1 μm and 10 μm, or in a range of 1 μm and 5 μm. In another embodiment, the coating 302 can have a thickness in a range of 5 μm and 20 μm, in a range of 10 μm and 20 μm, or in a range of 15 μm and 20 μm. In a particular embodiment, the coating 302 has a thickness of approximately 10 μm.

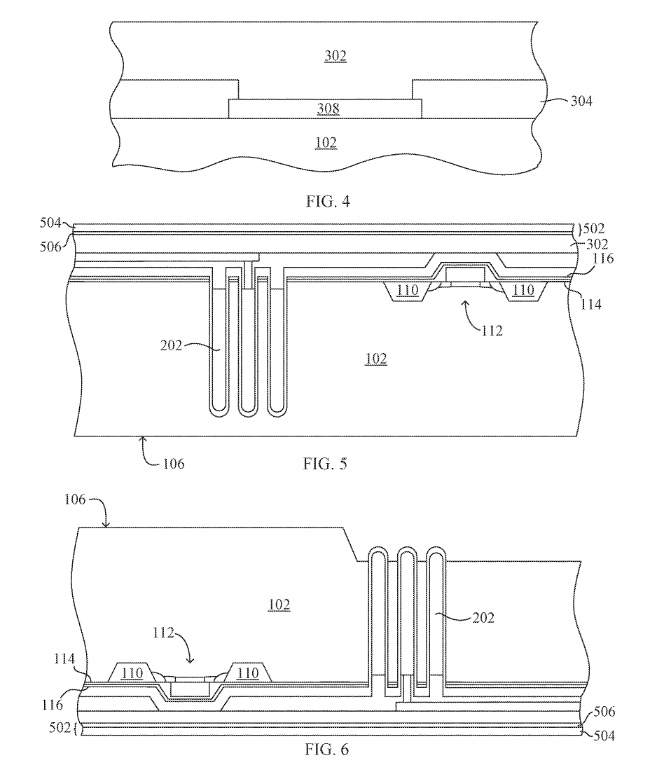

Referring to FIG. 5, in preparation for inverting the substrate 102, tape 502 is applied over the first surface 104. In an embodiment, the tape 502 is disposed over the coating 302 such that the coating 302 is disposed at least partially between the first surface 104 and the tape 502. In a particular embodiment, the tape 502 includes a backing 504 and a glue layer 506. The backing 504 can include a flexible material such as paper, foil, fabric, or film such as biaxially oriented polypropylene, polyvinyl chloride, a polyimide such as poly (4,4′-oxydiphenylene-pyromellitimide), or any combination thereof. The backing 504 can have a thickness in a range of 5 μm and 50 μm, in a range of 10 μm and 40 μm, in a range of 15 μm and 35 μm, or in a range of 20 μm and 30 μm. In a particular embodiment, the backing 504 has a thickness of approximately 26 μm. The backing 504 may be surface treated, for example, through a corona treatment or plasma process to increase bonding with the glue layer 506. One or more primers, sealants, other intermediary components, or combinations thereof can be coated along a portion, or all, of the backing 504. In an embodiment, the glue layer 506 includes an adhesive such as a pressure-sensitive adhesive (PSA). Exemplary PSA materials include acrylate polymer, rubber, silicone, or combinations thereof, optionally mixed with a tackifier. In an embodiment, the glue layer 306 can have a thickness in a range of 1 μm and 10 μm, in a range of 2 μm and 9 μm, or in a range of 3 μm and 8 μm. In a particular embodiment, the glue layer 506 has a thickness of approximately 5 μm. In an embodiment, an adhesiveness of the coating 302 is less than an adhesiveness of the glue layer 506.

As illustrated, the tape 502 is spaced apart from an exposed surface corresponding to the first surface 104 of the substrate 102 and an exposed portion of the via 202. In a particular embodiment, neither the backing 504 nor the glue layer 506 directly contacts the first surface 104 or any component disposed thereon (e.g., via 202). In a particular instance, a closest distance between the exposed surface and the tape 502 is at least 1 μm, at least 2 μm, at least 5 μm, or at least 10 μm. As discussed in greater detail below, the distance between the tape 502 and the exposed surface can permit removal of the tape 502 without deforming or detrimentally affecting the first surface 104 or any components disposed thereon which can cause device functional issues or failure.

After applying the tape 502 over the first surface 104, the substrate 102 is turned over so that the second surface 106 is facing upward (FIG. 6). The second surface 106 is then operated on, for example by removing a portion of the substrate 102 along the second surface 106 using a single operation or a plurality of operations. In an embodiment, removal can be performed using a relatively fast, nonselective removal technique, such as backgrinding, polishing, or the like. In an embodiment, the thickness of the substrate 102 can be sufficiently thick enough so that the workpiece does not excessively bow or otherwise become significantly non-planar during or after material removal. Thus, a handle does not need to be attached to the workpiece to keep the workpiece planar or otherwise allow the workpiece to be subsequently handled by machinery. In an embodiment, the thickness of the substrate 102 may be no greater than approximately 200 microns, no greater than approximately 170 microns, no greater than approximately 150 microns, or potentially thinner. The actual thickness selected may depend on the nominal size of the substrate 102, the stress on the substrate 102 due to other layers that are currently present, thermal cycles, and potentially other factors. In another embodiment, a substrate may already have a desired thickness. For example, the electronic device can be an interposer that has its desired thickness.

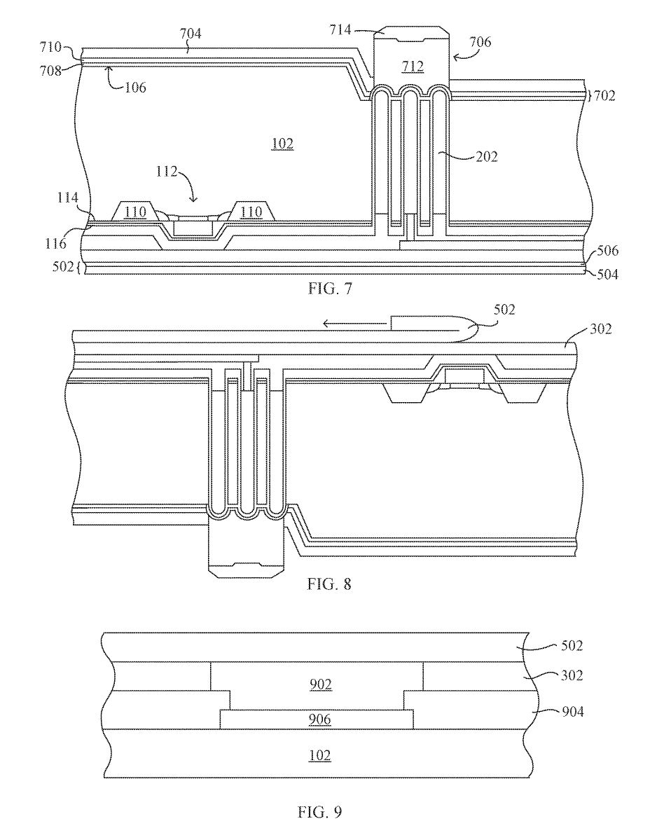

As illustrated in FIG. 7, a conductive layer 702, a mask layer 704, and a conductive bump 706 are formed along the workpiece. The conductive layer 702 can be part of underbump metallurgy and can include one or more films. In a particular embodiment, an adhesion film 708 helps the conductive bump 706 adhere better to insulating materials, such as portions of insulating layers within the trench 108. The adhesion film 708 can include titanium, tantalum, another suitable metal, or any combination thereof. A seed film 710 can help to promote plating of a conductive material within the conductive bump 706. The seed film 710 can be the same material as or different material from the conductive bump 706. The seed film 710 can include copper, a noble metal, or any combination thereof. In an embodiment, the thickness of the conductive layer 702 can be in a range of approximately 50 nm to 900 nm, and in a particular embodiment, can be in a range of approximately 70 nm to approximately 200 nm. Other thicknesses can be used if needed or desired.

The mask layer 704 defines openings where the conductive bumps, such as conductive bump 706, are formed. In a particular embodiment, the mask layer 704 may be a laminated layer. In another embodiment, the mask layer 704 can be deposited and patterned. The mask layer 704 includes an insulating material so that the conductive material within the conductive bumps is not formed over substantially all of the mask layer 704. During formation of the conductive bumps, some conductive material (overflow material) may be deposited onto the mask layer 704, but the overflow material will be near the openings and does not adversely affect the performance of the electronic device.

A conductive layer 712 and a solder layer 714 can be deposited within the openings to form the conductive bumps, such as the conductive bump 706. The conductive layer 712 may be electroplated over exposed portions of the seed film 710. The conductive layer 712 can include copper, a noble metal, or any combination thereof. In an embodiment, the conductive layer 712 can have a thickness greater than approximately 5 microns, greater than 20 microns, or greater than 40 microns. Although there is no theoretical upper number of the thickness, the conductive layer 712 may have a thickness no greater than approximately 900 microns, no greater than approximately 500 microns, or no greater than approximately 95 microns. The solder layer 714 can include a metal or a metal alloy that may flow at a temperature no greater than approximately 300° C., so that the solder layer 714 can flow (typically referred to as reflowing) and form an electrical connection to a different die, a packaging substrate, a printed wiring board, or the like. The solder layer 714 can include lead, indium, tin, another suitable material having desired flow characteristics, or any combination thereof. In an embodiment, the solder layer 714 can be significantly thinner than the conductive layer 712 and have a thickness that is in a range of approximately 5% to approximately 50% of the thickness of the conductive layer 712.

The conductive bump 706 can be subjected to a sufficiently high enough temperature to cause the solder layer 714 to flow. The uppermost points of solder layer 714, the conductive layer 712, or both may be at elevations, as measured from the central elevation, that are higher than the elevation of the second surface 106. Such elevation differences can allow for easier alignment to terminals of a packaging substrate, a printed wiring board, or another workpiece.

In another embodiment, the conductive bump 706 can be formed using a deposition technique, without the use of the conductive layer 712 or the mask layer 704. In an embodiment, a stencil mask (not illustrated) is placed over the substrate 102, wherein the stencil mask has openings where conductive bumps, similar to the conductive bump 706, are to be formed. The combination of the workpiece and stencil mask is placed into a deposition tool, and the underbump metallization and bump metallization can be sequentially deposited to form the conductive bumps. The use of the stencil mask may eliminate the need of a separate patterning step when forming the conductive bumps.

In still another embodiment, a lift-off process can be used. After forming the workpiece as illustrated in FIG. 5, a patterned resist layer can be formed such that openings defined by the resist layer overlying the openings where conductive bumps are to be formed. Underbump metallization can be deposited over the patterned resist layer and within the openings in the patterned resist layer and the openings. The patterned resist layer can be removed along with a portion of the underbump metallization overlying the patterned resist layer. Portions of the underbump metallization can remain in the openings. The bump metallization can be formed over the underbump metallization to form the conductive bumps. In a particular embodiment, the conductive bumps can be selectively formed over the underbump metallization, such as selective plating.

In a further embodiment, solder balls can be used in place of the conductive bumps. Each of the conductive bumps and the solder balls are examples of conductive structures that can directly contact the vias 202.

After formation of features along the second surface 106 of the substrate 102 is complete, or substantially complete, the substrate 102 can be reoriented such that the first surface 104 is facing upward. Referring to FIG. 8, the tape 502 is then removed, for example, by peeling from the tape 502 from the coating 302. In accordance with an embodiment described herein, the tape 502 is easier to remove when adhered to the coating 302 as compared to when adhered directly along the exposed surface of the first surface 104 and components disposed thereon. In an embodiment, a force required to remove the tape 502 from the coating 302 is no greater than 99.9% of a force required to remove tape from the exposed surface of the device, no greater than 99% of the force required to remove tape from the exposed surface of the device, no greater than 95% of the force required to remove tape from the exposed surface of the device, no greater than 90% of the force required to remove tape from the exposed surface of the device, or no greater than 75% of the force required to remove tape from the exposed surface of the device. The coating 302 can optionally be removed as well.

The device can then be subjected to further processing operations.

Referring to FIG. 9, an air cavity 902 can be formed between the tape 502 and the surface of the substrate 102. In an embodiment, the air cavity 902 has a height greater than a thickness of the coating 302. In another embodiment, the air cavity 902 has a height approximately equal to a thickness of the coating 302. In a further embodiment, it is possible to have an air cavity 902 with a height less than the thickness of the coating 302. The height of the air cavity 902 in accordance with an embodiment is less important than the inclusion of such air cavity 902. Inclusion of the air cavity 902 creates a gap between the glue layer of the tape 502 and the surface of the substrate 102 such that removal of the tape 502 does not deform or detrimentally affect the surface of the substrate 102 or any components disposed thereon, deformation of which can cause functional issues or device failure.

A bond pad 906 can overlie the substrate 102 beneath the air cavity 902. In an embodiment, the bond pad 906 includes a metal such as aluminum. A layer 904 between the substrate 102 and coating 302 can partially cover the bond pad 906. The layer 904 can include an oxide, a nitride, an oxynitride, a silicon nitride, another suitable material, or any combination thereof. The coating 302 can be disposed on the layer 904 so as to be disposed between the layer 904 and the tape 502. It is noted that inclusion of the layer 904 is optional. In certain embodiments, the coating 302 can be applied directly to at least a portion of the substrate 102 with the tape 502 disposed thereover.

Many different aspects and embodiments are possible. Some of those aspects and embodiments are described below. After reading this specification, skilled artisans will appreciate that those aspects and embodiments are only illustrative and do not limit the scope of the present invention. Embodiments may be in accordance with any one or more of the embodiments as listed below.

### Embodiment 1

A process of forming an electronic device comprising:
providing a substrate having a first surface and a second surface opposite the first surface;
etching the substrate along the first surface to define a trench;
forming a via within the trench;
applying a tape including an adhesive over the first surface, wherein the adhesive of the tape is spaced apart from the first surface by a distance; and
operating on the second surface of the substrate.

### Embodiment 2

The process of Embodiment 1, wherein an air cavity is disposed along the distance between the adhesive and the first surface of the substrate.

### Embodiment 3

The process of Embodiment 1, wherein a layer of polyimide is disposed between the adhesive of the tape and the first surface of the substrate.

### Embodiment 4

The process of Embodiment 1, further comprising:
removing the tape such that an exposed portion of the first surface of the substrate has less deformities as compared to a comparable process where tape is applied directly to an exposed portion of the first surface.

### Embodiment 5

The process of Embodiment 1, wherein operating on the second surface comprises:
removing a portion of the substrate using an isotropic etch; and
forming a first conductive structure along the second surface and electrically connected to the via.

### Embodiment 6

The process of Embodiment 5, wherein the first conductive structure comprises a bump or solder ball.

### Embodiment 7

A process of forming an electronic device comprising:
providing a substrate having a first surface and a second surface opposite the first surface;
etching the substrate along the first surface to define a trench;
forming a via within the trench;
forming a coating over the first surface after forming the trench;
applying a tape over the coating; and
removing a portion of the substrate along the second surface.

### Embodiment 8

The process of Embodiment 7, wherein forming the coating over the first surface is performed using a polyimide or a poly phenol resin.

### Embodiment 9

The process of Embodiment 7, further comprising:
removing the coating from the first surface after removing the portion of the substrate from the second surface.

### Embodiment 10

The process of Embodiment 7, wherein removing the coating is performed such that the first surface of the substrate has less deformities as compared to a comparable process where tape is applied directly to the first surface.

### Embodiment 11

The process of Embodiment 7, wherein forming the coating over the first surface is performed such that the coating has a thickness in a range of 1 μm and 20 μm.

### Embodiment 12

The process of Embodiment 7, wherein removing the portion of the substrate is performed using an isotropic etch.

### Embodiment 13

The process of Embodiment 7, wherein the tape comprises an a substrate and a glue layer, and wherein applying the tape is performed such that the glue layer of the tape is spaced apart from the first surface.

### Embodiment 14

A process of forming an electronic device comprising:
providing a substrate having a first surface and a second surface opposite the first surface;
etching the substrate along the first surface to define a trench;
forming a via within the trench;
forming a coating over the first surface;
applying a tape over the coating, the tape including a substrate and a glue layer, wherein the glue layer is spaced apart from an exposed surface of the substrate by the coating, and wherein the glue layer adheres less strongly to the coating as compared to a material along the exposed surface;
operating on the second surface of the substrate; and
removing the tape from the first surface.

### Embodiment 15

The process of Embodiment 14, wherein operating on the second surface comprises:
removing a portion of the substrate using an isotropic etch; and
forming a first conductive structure along the second surface and electrically connected to the via.

### Embodiment 16

The process of Embodiment 14, wherein forming the coating over the first surface is performed using a polyimide or a poly phenol resin.

### Embodiment 17

The process of Embodiment 14, wherein removing the coating is performed such that the first surface of the substrate has less deformities as compared to a comparable process where tape is applied directly to the first surface.

### Embodiment 18

The process of Embodiment 14, wherein forming a coating over the first surface is performed using a spin coating process.

### Embodiment 19

The process of Embodiment 14, wherein forming the coating over the first surface is performed such that the coating has a thickness in a range of 1 μm and 20 μm.

### Embodiment 20

The process of Embodiment 14, wherein an air cavity is disposed between the coating and the first surface of the substrate.

Note that not all of the features described above are required, that a portion of a specific feature may not be required, and that one or more features may be provided in addition to those described. Still further, the order in which features are described is not necessarily the order in which the features are installed.

Certain features are, for clarity, described herein in the context of separate embodiments, may also be provided in combination in a single embodiment. Conversely, various features that are, for brevity, described in the context of a single embodiment, may also be provided separately or in any subcombinations.

Benefits, other advantages, and solutions to problems have been described above with regard to specific embodiments, However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range, including the end range values referenced. Many other embodiments may be apparent to skilled artisans only after reading this specification. Other embodiments may be used and derived from the disclosure, such that a structural substitution, logical substitution, or any change may be made without departing from the scope of the disclosure. Accordingly, the disclosure is to be regarded as illustrative rather than restrictive.

1. A process of forming an electronic device comprising:
providing a substrate having a first surface and a second surface opposite the first surface;
etching the substrate along the first surface to define a trench;
forming a via within the trench;
forming a bond pad over the first surface of the substrate;
forming a coating over the first surface of the substrate, wherein the coating includes an opening that exposes the bond pad;
applying a tape including an adhesive over the first surface of the substrate, the bond pad, and the coating, wherein after applying the tape, an air cavity is disposed between the adhesive and the bond pad;
removing a portion of the substrate along the second surface while the tape overlies the first surface of the substrate; and
forming a first conductive structure along the second surface and electrically connected to the via, wherein forming the first conductive structure is performed after removing the portion of the substrate.

2. The process of claim 1, further comprising forming a layer after forming the bond pad and before forming the coating, wherein the layer includes an opening over the bond pad, and forming the coating is performed such that the opening of the coating overlies the opening of the layer.

3. The process of claim 1, wherein the coating comprises polyimide.

4. The process of claim 1, wherein the adhesive is spaced apart from the bond pad.

5. The process of claim 1, wherein removing the portion of the substrate is performed such that a portion of the via extends beyond the second surface of the substrate.

6. The process of claim 1, wherein the first conductive structure comprises a bump or solder ball.

7. A process of forming an electronic device comprising:
providing a substrate having a first surface and a second surface opposite the first surface, wherein the substrate includes a semiconductor material, and a transistor lies at least partly within the substrate along the first surface;
forming a bond pad over the first surface of the substrate;
etching the substrate along the first surface to define a trench;
forming a via within the trench;
forming a layer over the first surface of the substrate, wherein the bond pad underlies an opening in the layer;
forming a coating over the first surface of the substrate and the layer, wherein the coating includes an opening that overlies the opening in the layer, and the bond pad is exposed after forming the layer and the coating;
applying a tape over the first surface of the substrate, the bond pad, the layer, and the coating, wherein after applying the tape, an air cavity is disposed between the tape and the bond pad; and
removing a portion of the substrate along the second surface such that a portion of the via extends beyond the second surface of the substrate.

8. The process of claim 7, wherein the coating includes a polyimide or a poly phenol resin.

9. The process of claim 7, wherein the layer includes an oxide, a nitride, an oxynitride, or any combination thereof.

10. The process of claim 9, wherein the layer has a thickness in a range of 0.5 micron to 3.0 microns.

11. The process of claim 10, wherein the coating has a thickness in a range of 5 microns to 20 microns.

12. The process of claim 10, wherein the coating has a thickness in a range of 10 microns to 20 microns.

13. The process of claim 7, wherein the tape comprises a backing and a pressure-sensitive adhesive, and wherein applying the tape is performed such that the pressure-sensitive adhesive is spaced apart from the bond pad.

14. A process of forming an electronic device comprising:
providing a substrate having a first surface and a second surface opposite the first surface;
forming a bond pad over the first surface of the substrate;
forming a coating over the first surface of the substrate, wherein the coating includes an opening that exposes the bond pad;
applying a tape over the first surface of the substrate, the bond pad, and the coating, the tape including a substrate and a glue layer, wherein the glue layer is spaced apart from an exposed surface of the bond pad;
removing a portion of the substrate along the second surface of the substrate while the tape overlies the first surface of the substrate;
removing the tape from the first surface after removing the portion of the substrate along the second surface of the substrate; and
removing the coating.

15. (canceled)

16. The process of claim 14, wherein forming the coating over the first surface is performed using a polyimide or a poly phenol resin.

17. The process of claim 14, further comprising forming a layer after forming the bond pad and before forming the coating, wherein the layer includes an opening over the bond pad, and forming the coating is performed such that the opening of the coating overlies the opening of the layer.

18. The process of claim 17, wherein the layer has a thickness in a range of 0.5 micron to 3.0 microns.

19. The process of claim 18, wherein forming the coating over the first surface is performed such that the coating has a thickness in a range of 10 μm and 20 μm.

20. The process of claim 14, wherein the adhesive is a pressure-sensitive adhesive.

21. The process of claim 14, wherein forming the coating over the first surface is performed such that the coating has a thickness in a range of 5 μm and 20 μm.
